(19) United States
(12) Patent Application Publication
(10) Pub. No.: US 2020/0152686 A1
(43) Pub. Date: May 14, 2020

(54) STACKED TSV STRUCTURE AND MANUFACTURING METHOD THEREOF

(71) Applicant: HUAIAN IMAGING DEVICE MANUFACTURER CORPORATION, Huaian (CN)

(72) Inventors: Jing MA, HUAIAN (CN); Weiming ZHONG, HUAIAN (CN); Kishou KANEKO, HUAIAN (CN)

(73) Assignee: HUAIAN IMAGING DEVICE MANUFACTURER CORPORATION, HUAIAN (CN)

(21) Appl. No.: 16/511,885

(22) Filed: Jul. 15, 2019

(30) Foreign Application Priority Data
Nov. 9, 2018 (CN) 201811328173.0

(51) Int. Cl. H01L 27/146

(52) U.S. Cl. CPC H01L 27/14636; H01L 27/14643; H01L 27/1464; H01L 27/14683

(57) ABSTRACT

A stacked TSV structure comprises: a logic region in which a first metal wiring layer is formed, a pixel region located on the logic region, in which a second metal wiring layer is formed, and a through-silicon via including a first via penetrating from the first metal wiring layer upward through the logic region to the second metal wiring layer, wherein a contact is filled and formed in the through-silicon via, the contact contacting the first metal wiring layer and the second metal wiring layer, thereby electrically connecting the first metal wiring layer to the second metal wiring layer.

### CROSS-REFERENCE TO RELATED APPLICATIONS

This application claims priority to Chinese Patent Application No. 201811328173.0, filed on Nov. 9, 2018, which is hereby incorporated by reference in its entirety.

### TECHNICAL FIELD

The present disclosure relates to the field of semiconductors, and in particular to a stacked Through Silicon Via (also referred to as “TSV” for short) structure and a manufacturing method thereof.

### BACKGROUND

In recent years, along with the continuous development of processes, the laminated chip package has become a mainstream in the field of image sensors, particularly back-illuminated CMOS Image Sensors (CIS) The TSV technology realizes the interconnection of multiple layers of chips by realizing vertical conduction between chips and between wafers, increases the stacking density in the three-dimensional direction, reduces the overall dimension of the chips, improves the processing speed of the chips and reduces the power consumption of the chips. Generally, in an image sensor applying the TSV technology, a logic wafer and a pixel wafer are bonded together, a surface of the pixel wafer that is not bonded with the logic wafer is thinned, and then punching is performed on the thinned surface of the pixel wafer by using the TSV technology, so that the formed via penetrates through the pixel wafer to reach a metal wiring layer of the logic wafer, and subsequently, the via is filled with a metal medium, thereby realizing vertically interconnection between the circuit of the logic wafer and the circuit of the pixel wafer.

However, the TSV technology requires very deep vias to be fabricated on the pixel surface, and vias have large sizes, which would cause etching damages to the pixel surface and increase the dark current on the pixel wafer surface. Therefore, there is a demand to further optimize the stacked TSV structure.

### SUMMARY

An object of the present disclosure is to provide a novel stacked TSV structure and a corresponding manufacturing method thereof.

According to a first aspect of the present disclosure, a stacked TSV structure is provided, comprising: a logic region in which a first metal wiring layer is formed; a pixel region located on the logic region, in which a second metal wiring layer is formed; and a through-silicon via including a first via penetrating from the first metal wiring layer upward through the logic region to the second metal wiring layer, wherein a contact is filled and formed in the through-silicon via, the contact contacting the first metal wiring layer and the second metal wiring layer, thereby electrically connecting the first metal wiring layer to the second metal wiring layer.

According to a second aspect of the present disclosure, a method of manufacturing a stacked TSV structure is provided, comprising: providing a logic region, and forming a first metal wiring layer in the logic region; providing a pixel region, such that the pixel region is located on the logic region, and forming a second metal wiring layer in the pixel region; and forming a through-silicon via including a first via penetrating from the first metal wiring layer upward through the logic region to the second metal wiring layer, and filling a contact in the through-silicon via, the contact contacting the first metal wiring layer and the second metal wiring layer, thereby electrically connecting the first metal wiring layer to the second metal wiring layer.

According to a third aspect of the present disclosure, an image sensor is provided, comprising the stacked TSV structure according to the present disclosure.

According to a fourth aspect of the present disclosure, an imaging device is provided, comprising the image sensor including the stacked TSV structure according to the present disclosure.

Other features of the present disclosure and advantages thereof will become more apparent from the following detailed description of exemplary embodiments thereof with reference to the accompanying drawings.

### BRIEF DESCRIPTION OF THE DRAWINGS

The drawings, which are incorporated in and constitute a part of this description, illustrate embodiments of the present disclosure, and serve to explain the principles of the present disclosure together with the description.

The present disclosure may be more clearly understood from the following detailed description with reference to the drawings, wherein:

FIG. 1 shows a schematic cross-sectional view of a conventional stacked TSV structure.

FIG. 2 shows a schematic cross-sectional view of a stacked TSV structure according to one or more exemplary embodiments of the present disclosure.

FIG. 3 shows a flow chart of a method of manufacturing a stacked TSV structure according to one or more exemplary embodiments of the present disclosure.

FIGS. 4A-4F respectively show schematic cross-sectional views corresponding to respective steps for manufacturing a stacked TSV structure according to one or more exemplary embodiments of the present disclosure.

Note that in the embodiments described below, the same reference numeral is used in common between different drawings to denote the same part or parts having the same function, with omission of repeated description thereof. In the description, similar signs and letters represent similar items, so once a certain item is defined in one figure, no further discussion on it is required in the following figures.

To facilitate understanding, the positions, sizes, ranges, and the like of the respective structures shown in the drawings and the like sometimes do not mean to indicate actual positions, sizes, ranges, and the like. Therefore, the present disclosure is not limited to the positions, sizes, ranges and the like as disclosed in the drawings and the like.

### DETAILED DESCRIPTION

Various exemplary embodiments of the present disclosure will be described in detail below with reference to the drawings. It shall be noted that unless otherwise illustrated, respective arrangements, mathematic expressions and values of the components and steps illustrated in these embodiments do not limit the scope of the present disclosure.

The following descriptions on at least one illustrative embodiment are actually illustrative, but not mean to set any limitation on the present disclosure or its application or utilization. In other words, the semiconductor devices and manufacturing methods thereof herein are shown by way of example to illustrate various embodiments of the structures and methods in this disclosure. Those skilled in the art, however, will understand that they are merely illustrative, instead of exhaustive, of exemplary ways in which the present disclosure may be practiced. Furthermore, the drawings are not necessarily drawn in proportion, and some features may be amplified to show details of particular components.

Techniques, methods and devices that have already been known to ordinary technicians in the art may not be discussed here in detail, but under suitable circumstances, the techniques, methods and devices shall be deemed as parts of the granted description.

In the embodiments shown and discussed here, any specific value shall be interpreted as only illustrative, instead of limitative. Hence, other embodiments of the illustrative embodiments may have different values.

In the present disclosure, “one embodiment” or “some embodiments” means that features, structures, or characteristics described in connection with the embodiment is included in at least one embodiment or at least some embodiments of the present disclosure. Therefore, the appearances of the phrases “in one embodiment” or “in some embodiments” in various places throughout this disclosure are not necessarily referring to the same embodiment or embodiments. Furthermore, the features, structures, or characteristics may be combined in any suitable combination and/or sub-combination in one or more embodiments.

Herein, the term “pixel wafer” refers to a wafer in which pixel cells (also referred to as “pixel regions”) are formed, and the term “logic wafer” refers to a wafer in which signal processing circuits for logic cells (also referred to as “logic regions”) are formed.

The technology of the present disclosure will be explained in detail below with reference to the drawings.

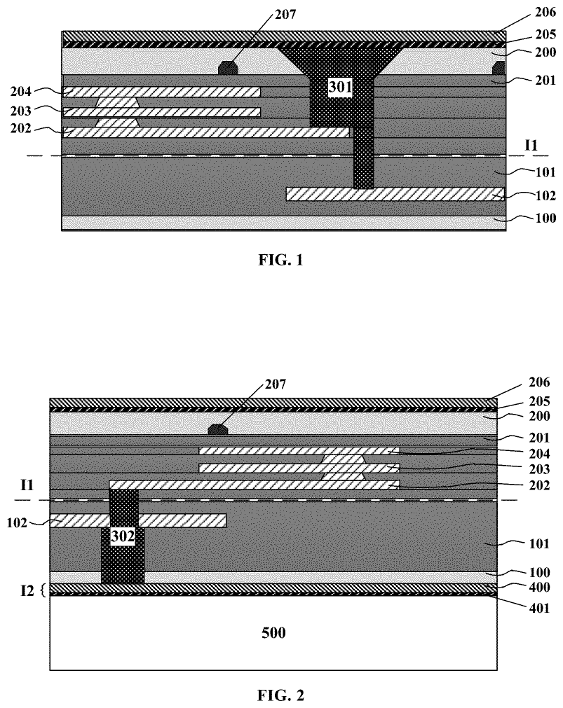

FIG. 1 shows a schematic cross-sectional view of a conventional stacked TSV structure.

As shown in FIG. 1, a conventional stacked TSV structure comprises:

a logic substrate 100 in which transistor parts (not shown) serving as signal processing circuits are formed;

an Inter Level Dielectric (also referred to as “ILD” for short) layer 101 located on the logic substrate 100;

a first metal wiring layer 102 located in the ILD layer 101;

a first interlayer I1 located on the first metal wiring layer 102, the first interlayer bonding the logic wafer with the pixel wafer;

a second metal wiring layer 202 located on the first interlayer I1;

a plurality of metal wiring layers which are located on the second metal wiring layer 202 and spaced up and down, such as metal wiring layers 203 and 204, the plurality of metal wiring layers being vertically conducted and being conducted with the second metal wiring layer;

an ILD layer 201 located on the plurality of metal wiring layers;

a pixel substrate 200 located on the ILD layer 201, wherein shallow trench isolation parts 207 are arranged on the ILD layer 201 in the pixel substrate 200 for separating respective pixel units so as to avoid mutual influence among the pixel units;

a through-silicon via 301 penetrating through the pixel substrate 200 to the first metal wiring layer 102, wherein the through-silicon via 301 is filled with a contact formed therein;

an oxide layer 205 located on the pixel substrate 200 and the through-silicon via 301; and

a dielectric layer 206 located on the oxide layer 205.

As shown in FIG. 1, the logic wafer includes a logic substrate 100, an ILD layer 101 and a first metal wiring layer 102. The pixel wafer includes a pixel substrate 200, an ILD layer 201, a second metal wiring layer 202, metal wiring layers 203 and 204, an oxide layer 205, a dielectric layer 206 and shallow trench isolation parts 207.

Note that, in this disclosure, numbers including “first”, “second” and the like are merely used for distinguishing different components having the same nomination, while not not mean order, positional relationship, or the like. In addition, for each of the different components having the same nomination, such as “first metal wiring layer” and “second metal wiring layer”, etc., it does not mean that they all have the same structures or parts.

In some embodiments, the substrate 100/200 may be a semiconductor substrate made of any semiconductor material suitable for a semiconductor device, such as Si, SiC, SiGe, or the like. In other embodiments, the substrate 100/200 may be a composite substrate of Silicon On Insulator (SOI), silicon germanium on insulator, or the like. Those skilled in the art will appreciate that the substrate is not limited in any way and may be selected according to practical application. Various device (not limited to a semiconductor device) members (not shown in the figure) may be formed in the substrate 100/200. Although not shown in the figure, other layers or members, such as gate structures, contact holes, ILD layers, underlying metal wires and vias, etc., may also be formed on the substrate 100/200.

In addition, as shown in FIG. 1, in some embodiments, the through-silicon via 301 may include a via (large hole above) that passes through the pixel substrate 200 to reach a portion (left portion) of the second metal wiring layer 202, and a via (small hole below) that passes through the pixel cell to reach a portion of the first metal wiring layer 102. Wherein the two vias communicate with each other and may be formed as a whole.

As shown in FIG. 1, the TSV technology requires a via to be formed on the surface of the pixel substrate 200, while forming a via on the surface of and through the pixel substrate, which would always cause etching damages to the pixel surface, resulting in an increase in dark current on the pixel surface. Furthermore, the via and the metal wiring layer may not be precisely aligned, resulting in a low chip yield. In view of this, an improvement is made to the stacked TSV structure in the present disclosure.

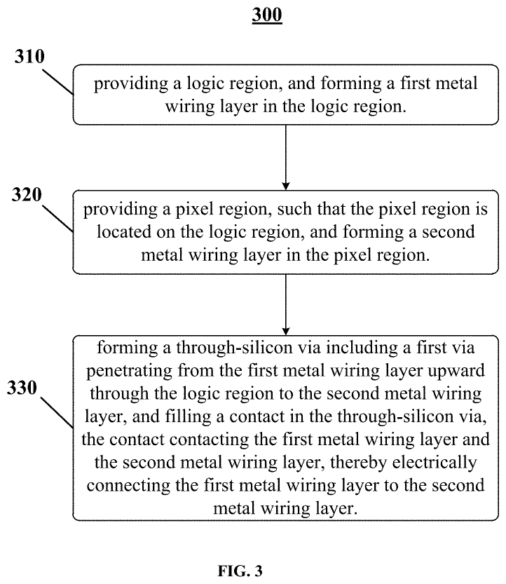

FIG. 2 shows a schematic cross-sectional view of a stacked TSV structure according to one or more exemplary embodiments of the present disclosure.

As shown in FIG. 2, the structure of the present disclosure changes the position of the through-silicon via as compared to the conventional stacked TSV structure as shown in FIG. 1. Specifically, the present disclosure changes perforating from the surface of the pixel substrate as perforating from the surface of the logic substrate, thereby reducing the dark current on the surface of the pixel substrate while also reducing etching damages. In addition, the present disclosure eliminates the need to etch deep hole structures through the pixel cells, thereby reducing semiconductor processes to some extent and reducing the amount of metal required to fill the contact in the via.

As shown in FIG. 2, the first metal wiring layer 102 is mainly divided into two parts, i.e., a left part and a right part. The through-silicon via 302 includes a first via (small hole above) that passes from the first metal wiring layer 102 up through the logic region to the second metal wiring layer 202 and a second via (large hole below) that passes through the logic substrate 100 of the logic region to the first metal wiring layer 102. Wherein a contact is filled and formed in the through-silicon via 302, the contact contacting the first metal wiring layer 102 and the second metal wiring layer 202, thereby electrically connecting the first metal wiring layer 102 to the second metal wiring layer 202.

According to the embodiment, FIG. 2 further shows a carrier wafer 500 carrying a logic cell and a pixel cell and bonded to the logic substrate 100 of the logic cell through a second interlayer 12.

According to the embodiment, the second interlayer 12 includes a dielectric layer 400 and an oxide layer 401 that are bonded together.

In addition, the respective layers and structures in this embodiment having the same numbers as in FIG. 1 have the same or similar functions as described above, and thus the corresponding description thereof is omitted herein.

It will be appreciated by those skilled in the art that the stacked TSV structure as shown in FIG. 2 is not necessarily the final product, but in some cases subsequent processing may be performed, such as manufacturing color filters and micro-lenses and the like on the backside thereof in case of a back-illuminated CMOS image sensor, but these are not the key points of the present disclosure and are not shown in the figures.

Preferably, the second via of the through-silicon via 302 is communicated with the first via, and has a diameter larger than or equal to that of the first via. Preferably, the second via and the first via may be formed as a whole, i.e., integrally formed.

Preferably, the first metal wiring layer 102 and the second metal wiring layer 202 include copper. For example, the first metal wiring layer 102 is a copper wiring layer embedded and formed in the ILD layer 101. The second metal wiring layer 202 is also a copper wiring layer embedded and formed in the ILD layer 201.

Preferably, the contacts filled in the through-silicon vias 301, 302 comprise copper, and are formed by an electroplating process and a subsequent Chemical Mechanical Polishing (CMP) process, such that the bottom ends of the contacts are flush with the bottom ends of the through-silicon via 302, as shown in FIG. 2.

In addition, it will be understood by those skilled in the art that the metal used to manufacture the contacts, the first metal wiring layer, and the second metal wiring layer may include a variety of other conductive metals, which are not limited to copper, but may also include aluminum, for example.

In many cases, the stacked TSV structure according to the present disclosure is formed by bonding logic cells and pixel cells. For example, the reference numeral “I1” in FIG. 2 indicates a horizontal dotted line passing through the first interlayer, which represents a bonding interface, and the first interlayer I1 includes a dielectric layer and an oxide layer (not shown) bonded together.

In this case, in the figure, the region above the bonding interface I1 is a pixel region, and the region below the bonding interface I1 is a logic region. The pixel region is bonded upside down on the logic region, so that the front surface of the pixel region is actually a surface of the pixel region facing the lower side in the figure, the back surface of the pixel region is a surface of the pixel region facing the upper side in the figure, while the front surface of the opposite logic region is a surface of the logic region facing the upper side in the figure, and the back surface of the logic region is a surface of the logic region facing the lower side in the figure.

In addition, although FIG. 2 shows only one metal layer, i.e., the first metal wiring layer 102, in the logic region, it should be understood by those skilled in the art that the logic region may actually contain more metal wiring layers, and the TSV is not limited to connecting the metal wiring layer closest to the front surface of the logic region, but may connect other metal wiring layers as needed. Also, the metal wiring layers in the pixel region are not limited to the metal wiring layers 202 to 204 as shown in FIG. 2, but may include more metal wiring layers. In addition, the TSV is not limited to being connected to the metal wiring layer closest to the front surface of the pixel region, but may connect other metal wiring layers as needed, and accordingly, the metal wiring layer electrically connected to the TSV extends a longer distance in the horizontal direction than the other metal wiring layers.

In addition, it shall be understood by those skilled in the art that although not shown, the ILD layers 101, 201 in FIG. 2 may comprise multiple ILDs.

In addition, although the pixel substrate 200 is described as being used to form a pixel cell, it shall be understood by those skilled in the art that other necessary devices, components, and the like may be included in the pixel substrate 200 in addition to the pixel cell.

In addition, those skilled in the art will appreciate that the shape of the contacts and the shape of the vias of the present disclosure are not limited to the shapes as shown in the figures, but may vary according to process or design requirements.

Preferably, the oxide layer 205 may be formed by an Atomic Layer Deposition (ALD) technology. The dielectric layer 206 may include silicon nitride (SiN), which may be formed by TEOS.

In addition, although not shown in the figures, it shall be understood by those skilled in the art that components such as color filters and micro-lenses may also be formed on the dielectric layer 206 in the pixel region according to need.

Note that this example is not intended to constitute a limitation to the present disclosure. For example, the present disclosure is not limited to the specific structure as shown in FIG. 2, but is applicable to all stacked TSV structures having the same requirements or design considerations. The above description with reference to FIG. 2 may also be applied to the corresponding features.

FIG. 3 shows a flow chart of a method of manufacturing a stacked TSV structure according to one or more exemplary embodiments of the present disclosure.

In particular, as shown in FIG. 3, at step 310, a logic region is provided, and a first metal wiring layer is formed in the logic region. At step 320, a pixel region is provided on the logic region, and a second metal wiring layer is formed in the pixel region.

Although in the flow chart as shown in FIG. 3, step 310 precedes step 320, the present disclosure is not limited thereto. It should be understood by those skilled in the art that the logic region and the pixel region may be formed independently of each other, the order in which they are manufactured is not limited in any way, and they may be manufactured simultaneously.

In some embodiments, the first metal wiring layer and the second metal wiring layer are formed of copper, and the forming step may include: depositing a copper layer on a substrate, and patterning the copper layer by using photoetching and etching processes to form the first metal wiring layer and the second metal wiring layer.

Subsequently, at step 330, a through-silicon via including a first via penetrating from the first metal wiring layer upward through the logic region to the second metal wiring layer is formed, and a contact is filled in the through-silicon via, the contact contacting the first metal wiring layer and the second metal wiring layer, thereby electrically connecting the first metal wiring layer to the second metal wiring layer.

In some embodiments, the through-silicon via is further formed to include a second via penetrating through a logic substrate of the logic region to the first metal wiring layer, wherein the second via communicates with the first via, and has a diameter larger than or equal to that of the first via.

In some embodiments, before forming the through-silicon via, a surface of the logic substrate on a side opposite to the pixel region may be thinned, that is, a back surface of the logic region opposite to the bonding surface may be thinned for the logic substrate.

In some embodiments, the step of forming a through-silicon via comprises: etching the logic substrate from the back side of the logic region (e.g., thinned) until reaching the first metal wiring layer, thereby forming the second via; and etching a part of the first metal wiring layer exposed through the second via and continuously etching the material below it until reaching the second metal wiring layer, thereby forming the first via.

In some embodiments, the step of forming the contact comprises using an electroplating process to generate a copper material to fill the through-silicon via, and then performing a CMP process on the copper material to form a contact with a bottom end flushing with a bottom end of the through-silicon via.

In some embodiments, a first interlayer may be formed between the logic region and the pixel region, the logic region and the pixel region being bonded together through the first interlayer.

In some embodiments, a carrier wafer may be provided, such that the carrier wafer carries the logic region and the pixel region and is bonded with the logic region through a second interlayer.

In some embodiments, the first interlayer or the second interlayer may include a dielectric layer and an oxide layer that are bonded together.

In some embodiments, the through-silicon via may be formed by a deep silicon etching process.

In some embodiments, the contact, the first metal wiring layer and the second metal wiring layer may include copper.

In some embodiments, a plurality of metal wiring layers which are spaced up and down may be formed in the pixel region, and the plurality of metal wiring layers are vertically conducted and are conducted with the second metal wiring layer.

In addition, it shall be understood by those skilled in the art that this example of the flow chart is not intended to constitute a limitation to the present disclosure. Although the present disclosure illustrates only thinning the chip after manufacture of the metal wiring layer and then manufacturing the via, which is connected to the circuit after its manufacture, it should be understood that the present disclosure may also manufacture the via immediately after wafer bonding and then perform subsequent process treatments, and it may also manufacture the via after all subsequent process treatments are completed, and may also manufacture the via after partial processes are performed after bonding. In addition, in the present disclosure, the TSV structure may be manufactured after the silicon chip is thinned and scribed.

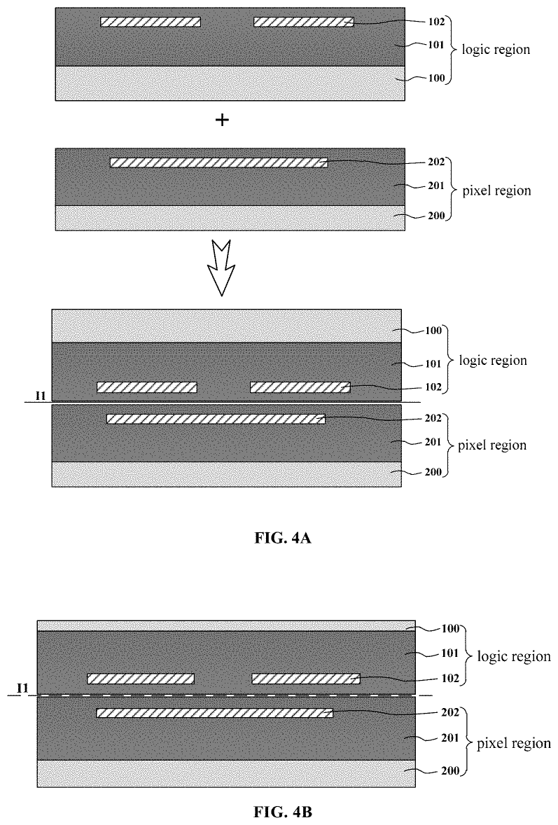

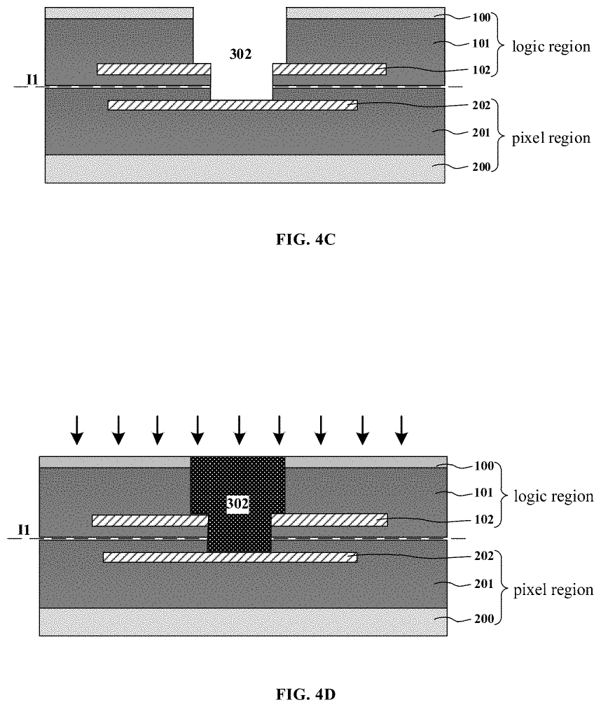

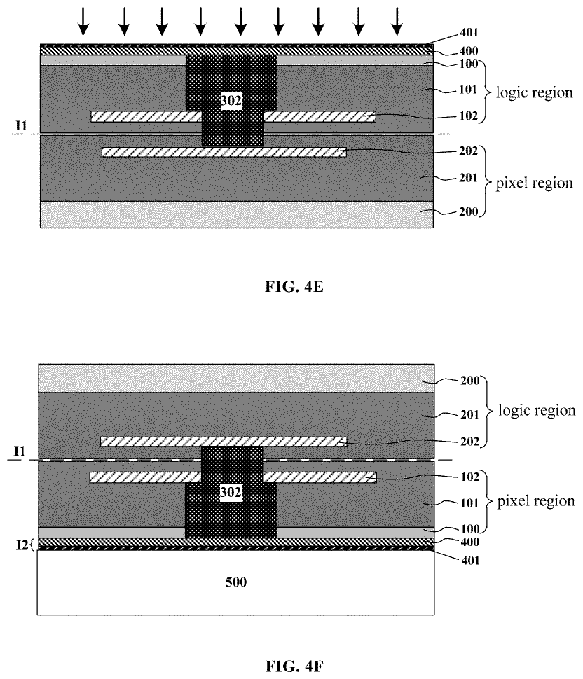

For entire and overall understandings on the present disclosure, FIGS. 4A-4F respectively show schematic cross-sectional views corresponding to respective steps for manufacturing a stacked TSV structure according to one or more exemplary embodiments of the present disclosure.

In FIG. 4A, the pixel region and the logic region (not cut into single pieces, and also referred to as a “pixel wafer” and a “logic wafer”) are typically bonded together at the wafer level. The horizontal dotted line I1 in the figure represents a bonding interface between the pixel region and the logic region, with the logic region above I1 and the pixel region below I1. Preferably, the pixel region and the logic region are bonded together through a first interlayer (not shown), which may include a dielectric layer and an oxide layer that are bonded together.

Prior to the bonding, the logic region includes: a logic substrate 100; an ILD layer 101 located on the logic substrate 100; and an outermost metal wiring layer (i.e., a first metal wiring layer) 102 located in the ILD layer 101.

Prior to the bonding, the pixel region includes: a pixel substrate 200; an ILD layer 201 located on the pixel substrate 200; and an outermost metal wiring layer (i.e., a second metal wiring layer) 202 located in the ILD layer 201.

Although the logic region is shown inverted over the pixel region in FIG. 4A, it is noted that the top-bottom orientation is only a relative concept herein, and it should be understood by those skilled in the art that the present disclosure is not limited to the case where the logic region is inverted over the pixel region, but may have inverted positions where the positional relationship of the layers of the stacked semiconductor device is correspondingly inverted. In some cases, it is preferred to place a wafer with a relatively large wafer bow underneath during the bonding process of the two wafers. In this case, however, after the wafer bonding is completed, it is also possible to determine whether the structure is to be turned upside down or not according to practical requirements, thereby determining which wafer is on the top and which wafer is on the bottom finally.

Subsequently, as shown in FIG. 4B, a thinning process is performed on the back surface of the logic substrate 100 opposite to the pixel region. Preferably, the thinning process is performed using the CMP process and the wet cleaning.

Next, as shown in FIG. 4C, after thinning, a second via (an upper large hole) and a first via (a lower small hole) may be formed on the back surface of the logic substrate 100 in sequence by a two-step etching process to form a through-silicon via 302. Preferably, the second via is communicated with the first via, and has a diameter larger than or equal to that of the first via.

Next, at FIG. 4D, a conductive material (e.g., copper) is filled in the through-silicon via 302 (including the first via and the second via) to form a contact such that the contact contacts the first metal wiring layer 102 and the second metal wiring layer 202, thereby electrically connecting the first metal wiring layer 102 to the second metal wiring layer 202. For example, the step of filling copper in the through-silicon via (TSV) may include: firstly forming a liner layer (e.g., Ta/TaN) on the walls of the through-silicon via 301 by CVD, PVD or other deposition techniques, the linear layer isolating the copper to be filled in the through-silicon via 301 from the outside to avoid copper diffusion and make the copper more easily to be adherent to the walls of the through-silicon via 301; then forming a copper seed layer on the liner layer through PVD or other techniques, and filling the copper through a copper electroplating process; finally, a CMP process is used to planarize the top surface of the filled copper, thereby forming a contact whose top is flush with the top of the through-silicon via 301.

Next, in FIG. 4E, a dielectric layer 400 and an oxide layer 401 are sequentially formed from the back surface of the logic region by the deposition process.

Next, in FIG. 4F, the pixel region and the logic region are flipped, and the back side of the logic region is bonded to the carrier wafer through the second interlayer 12. In FIG. 4F, the region above the bonding interface 12 is the logic region, and the region below the bonding interface 12 is the carrier wafer. The second interlayer 12 includes a dielectric layer 400 and an oxide layer 401 that are bonded together.

Finally, after the whole manufacturing process of the stacked TSV structure is completed, the bonded wafer can be sliced, so as to form individual stacked TSV structures.

Those skilled in the art will appreciate that the present disclosure further includes any other processes and structures necessary to form a stacked TSV structure in addition to the processes and structures as illustrated.

In addition, in some embodiments, the present disclosure also provides an image sensor including the stacked TSV structure as described above and an imaging apparatus including the sensor.

By utilizing the stacked TSV structure of the present disclosure, perforation on the surface of the pixel substrate is avoided, and the dark current and the etching damage on the surface of the pixel substrate are effectively reduced. In addition, the present disclosure eliminates the need to etch deep hole structures through the pixel cells, thereby reducing semiconductor processes and reducing the amount of metal required to fill the contact in the via. Furthermore, the stacked TSV structure of the present disclosure does not need to avoid the metal wiring layer of the pixel region closest to the front surface of the pixel region as in the conventional TSV structure, but instead, it could be vertically and integrally formed using the through-silicon via technology, thereby improving the alignment precision.

The terms “front”, “back”, “top”, “bottom”, “above”, “below” and the like in the description and in the claims, if any, are used for descriptive purposes and not necessarily for describing constant relative positions. It should be understood that the terms thus used are interchangeable under appropriate circumstances such that the embodiments of the disclosure as described herein are, for example, capable of being operated in other orientations different than those as illustrated or otherwise described herein.

As used herein, the word “exemplary” means “serving as an example, instance, or illustration”, instead of serving as a “model” that is to be accurately reproduced. Any implementation illustratively described herein is not necessarily to be construed as preferable or advantageous over other implementations. Furthermore, the present disclosure is not limited by any expressed or implied theory presented in the preceding parts of Technical Field, Background, Summary or Detailed description.

As used herein, the term “substantially” is intended to encompass any minor variation caused by design or manufacturing imperfections, tolerances of devices or components, environmental influences, and/or other factors. The word “substantially” also allows for differences from a perfect or ideal situation due to parasitic effect, noise, and other practical considerations that may exist in a practical implementation.

Additionally, for reference purposes only, similar terms as “first”, “second” and the like may also be used herein, and are not intended to be limiting. For example, the terms “first”, “second” and other such numerical terms relating to structures or elements do not imply a sequence or order unless clearly indicated by the context.

It will be further understood that the term “comprising/including”, when used herein, specifies the presence of stated features, integers, steps, operations, units and/or components, while does not mean to exclude the presence or addition of one or more other features, integers, steps, operations, units and/or components, and/or combinations thereof.

In the present disclosure, the term “providing” is used in a broad sense to cover all ways of obtaining an object, and thus “providing an object” includes, but is not limited to, “purchasing”, “preparing/manufacturing”, “arranging/setting”, “installing/assembling”, and/or “ordering” an object, etc.

The above description may indicate elements or nodes or features that are “connected” or “coupled” together. As used herein, the term “connecting” means one element/node/feature is electronically, mechanically, logically or directly in other manners connected (or directly communicates) with another element/node/feature, unless otherwise illustrated. Similarly, unless otherwise illustrated, the term “coupling” means one element/node/feature may be mechanically, electronically, logically or otherwise linked to another element/node/feature in a directly or indirect manner to allow an interaction therebetween, even if these two features may not be connected directly. In other words, the term “coupling” intends to include directly links and indirect links between elements or other features, including connections through one or more intermediate elements.

It shall be realized by those skilled in the art that boundaries between said operations are only illustrative. Multiple operations may be combined into a single operation, and a single operation may be distributed in additional operations, and moreover, the operations may be performed in an at least partially overlapping manner in time. Furthermore, optional embodiments may include multiple examples of specific operations, and the operation sequence may be changed in various other embodiments. However, other modifications, changes and replacements are also possible. Thus, the description and drawings shall be deemed as illustrative instead of limitative.

Although some specific embodiments of the present disclosure have been exemplified in detail, it shall be understood by those skilled in the art that the above examples are only illustrative, not mean to limit the scope of the present disclosure. The respective examples of the disclosure may be combined in any manner, without departure from spirits and scope of the present disclosure. It shall further be understood by those skilled in the art that multiple modifications may be made to the examples, without departure from the scope and spirits of the present disclosure. The scope of the present disclosure is defined by the attached claims.

What is claimed is:

1. A stacked TSV structure, comprising:
a logic region in which a first metal wiring layer is formed;
a pixel region located on the logic region, in which a second metal wiring layer is formed; and
a through-silicon via including a first via penetrating from the first metal wiring layer upward through the logic region to the second metal wiring layer, wherein a contact is filled and formed in the through-silicon via, the contact contacting the first metal wiring layer and the second metal wiring layer, thereby electrically connecting the first metal wiring layer to the second metal wiring layer.

2. The stacked TSV structure according to claim 1, wherein:
the through-silicon via further includes a second via penetrating through a logic substrate of the logic region to the first metal wiring layer.

3. The stacked TSV structure according to claim 2, wherein:
the second via is communicated with the first via, and has a diameter larger than or equal to that of the first via.

4. The stacked TSV structure according to claim 1, further comprising:
a first interlayer located between the logic region and the pixel region, the logic region and the pixel region being bonded together by the first interlayer; and
a carrier wafer, carrying the logic region and the pixel region and being bonded with the logic region by a second interlayer.

5. The stacked TSV structure according to claim 4, wherein:
the first interlayer or the second interlayer includes a dielectric layer and an oxide layer that are bonded together.

6. The stacked TSV structure according to claim 1, wherein:
the through-silicon via is formed by a deep silicon etching process.

7. The stacked TSV structure according to claim 1, wherein:
the contact includes copper.

8. The stacked TSV structure according to claim 1, wherein:
the first metal wiring layer and the second metal wiring layer include copper.

9. The stacked TSV structure according to claim 1, wherein:
the pixel region further includes a plurality of metal wiring layers which are spaced up and down, and the plurality of metal wiring layers are vertically conducted and are conducted with the second metal wiring layer.

10. A method of manufacturing a stacked TSV structure, comprising:
providing a logic region, and forming a first metal wiring layer in the logic region;
providing a pixel region, such that the pixel region is located on the logic region, and forming a second metal wiring layer in the pixel region; and
forming a through-silicon via including a first via penetrating from the first metal wiring layer upward through the logic region to the second metal wiring layer, and filling a contact in the through-silicon via, the contact contacting the first metal wiring layer and the second metal wiring layer, thereby electrically connecting the first metal wiring layer to the second metal wiring layer.

11. The method according to claim 10, further comprising:
the through-silicon via is further formed to include a second via penetrating through a logic substrate of the logic region to the first metal wiring layer.

12. The method according to claim 11, wherein:
the second via is communicated with the first via, and has a diameter larger than or equal to that of the first via.

13. The method according to claim 10, further comprising:
thinning a surface of the logic substrate opposite to the pixel region before forming the through-silicon via.

14. The method according to claim 10, further comprising:
forming a first interlayer between the logic region and the pixel region, the logic region and the pixel region being bonded together by the first interlayer; and
providing a carrier wafer, such that the carrier wafer carries the logic region and the pixel region and is bonded with the logic region by a second interlayer.

15. The method according to claim 14, wherein:
the first interlayer or the second interlayer includes a dielectric layer and an oxide layer that are bonded together.

16. The method according to claim 10, wherein:
the through-silicon via is formed by a deep silicon etching process.

17. The method according to claim 10, wherein:
the contact includes copper.

18. The method according to claim 10, wherein:
the first metal wiring layer and the second metal wiring layer include copper.

19. The method according to claim 10, wherein:
a plurality of metal wiring layers which are spaced up and down are formed in the pixel region, such that the plurality of metal wiring layers are vertically conducted and are conducted with the second metal wiring layer.

20. An image sensor, comprising the stacked TSV structure according to claim 1.
